(19) United States
(12) Patent Application Publication
(10) Pub. No.: US 2025/0024751 A1
(43) Pub. Date: Jan. 16, 2025

(54) 2D/3D PEROVSKITE HETEROJUNCTION FOR ELECTRONIC DEVICE AND METHOD

(71) Applicant: KING ABDULLAH UNIVERSITY OF SCIENCE AND TECHNOLOGY, Thuwal (SA)

(72) Inventors: Erkan AYDIN, Thuwal (SA); Randi AZMI, Thuwal (SA); Michele DE BASTIANI, Thuwal (SA); Stefaan DE WOLF, Thuwal (SA)

(21) Appl. No.: 18/711,364

(22) PCT Filed: Nov. 17, 2022
(86) PCT No.: PCT/IB2022/061110

§ 371 Date: May 17, 2024

Related U.S. Application Data
(60) Provisional application No. 63/280,697, filed on Nov. 18, 2021.

(51) Int. Cl. H10K 85/50; H10K 30/10; H10K 30/40; H10K 39/10; H10K 71/40; H10K 85/20; H10K 85/60

(52) U.S. Cl. CPC H10K 85/50; H10K 30/10; H10K 30/40; H10K 39/10; H10K 71/40; H10K 85/211; H10K 85/654; H10K 85/6572

(57) ABSTRACT

A perovskite solar cell for converting solar energy into electricity includes a substrate, a 3D perovskite layer located on the substrate, and a 2D perovskite layer directly located on the 3D perovskite layer. The 2D perovskite layer is anchored to the 3D perovskite layer with oleylammonium-iodide (OLAI) molecules, and each of the 2D and 3D perovskite layer includes the same perovskite material.

### CROSS-REFERENCE TO RELATED APPLICATIONS

This application claims priority to U.S. Provisional Patent Application No. 63/280,697, filed on Nov. 18, 2021, entitled “2D/3D PEROVSKITE HETEROJUNCTIONS FOR ELECTRONIC DEVICE APPLICATIONS,” the disclosure of which is incorporated herein by reference in its entirety.

### BACKGROUND OF THE INVENTION

### Technical Field

Embodiments of the subject matter disclosed herein generally relate to perovskite solar cells having high power conversion efficiencies, and more particularly, to such solar cells that have a long-term stability to ambient humidity and heat.

### Discussion of the Background

The power conversion efficiency (PCE) of perovskite solar cells (PSCs) has continued to grow, with a demonstrated PCE exceeding 25% in 2021. However, fabricating efficient PSCs is not enough to bring this technology to market readiness. For this purpose, the long-term stability, which is routinely assessed for commercial PV modules via accelerated degradation test, must be guaranteed. Damp-heat testing (performed at 85° C./85% of relative humidity), following the widely recognized International Electrotechnical Commission (IEC 61215:2016) standards, is the ideal standard degradation test in the PV industry. This test requires less than 5% PCE loss over 1000 h of continuous exposure to the hot and humid environment. So far, no studies have reported on PSCs retaining a stabilized PCE at the efficiency level of commercial c-Si solar cells (PCE˜20%) after damp-heat test.

The degradation of the encapsulated PSCs is usually caused by leakage in the packaging (i.e., allowing atmospheric agents to interact with the perovskite) and device-related material instability. This interaction induces the instability of the three-dimensional (3D) perovskite films, which are used as the absorber layer in PSCs. The degradation induced by the interaction with the atmospheric agents is mainly attributed to high defect densities and ion migration at grain boundaries and interfaces, exacerbated at higher operational temperatures. Several approaches have been reported to passivate these defects [1 to 5]. One such approach includes forming two-dimensional perovskite (2DP) layers on the top surface of 3DPs, thereby creating a 3D/2D perovskite heterojunction. This approach has been found to effectively passivate surface defects and suppress ion migration [6 to 12].

At the device level, integrating such 2D perovskite passivation (2DPP) layers in PSCs has been found to enhance their PCE and lifetime [6, 8-11]. So far, this 3D/2D perovskite heterojunction strategy has been most successful for regular structured n-i-p PSCs, employing phase-pure 2DP (n=1, where n represents the dimensionality of the 2DP, by counting the number of its octahedral inorganic sheets), inserted between the 3DP surface and the hole transporting top contact with a thermal annealed step. However, for the inverted p-i-n devices, to date, this top-contact passivation approach has consistently failed, representing a persistent challenge in the perovskite community [13, 14], as the inverted p-i-n PSCs are arguably easier to fabricate and scale-up [3].

Thus, there is a need for a new approach to the implementation of 3D/2D perovskite heterojunction strategy for inverted p-i-n devices that preserve the high-power conversion efficiency while simultaneously become resistant to damp-heat conditions.

### SUMMARY OF THE INVENTION

According to an embodiment, there is a perovskite solar cell for converting solar energy into electricity. The perovskite solar cell includes a substrate, a 3D perovskite layer located on the substrate, and a 2D perovskite layer directly located on the 3D perovskite layer. The 2D perovskite layer is anchored to the 3D perovskite layer with oleylammonium-iodide (OLAI) molecules. Each of the 2D and 3D perovskite layer includes the same perovskite material.

According to another embodiment, there is a solar cell module that converts solar energy into electrical energy. The solar cell module includes a substrate, plural solar cells formed onto the substrate, and electrical connections that electrically connect in series the plural solar cells. A solar cell of the plural solar cells includes a 3D perovskite layer, and a 2D perovskite layer directly located on the 3D perovskite layer. The 2D perovskite layer is anchored to the 3D perovskite layer with oleylammonium-iodide (OLAI) molecules, and each of the 2D and 3D perovskite layer includes the same perovskite material.

According to another embodiment, there is a method for forming a perovskite solar cell, and the method includes forming an indium tin oxide, ITO, layer on a substrate, depositing a hole extraction layer on the ITO layer, forming 3D perovskite layer on the hole extraction layer, passivating a top surface of the 3D perovskite layer with oleylammonium-iodide, OLAI molecules to form a 2D perovskite passivation layer, and annealing the 3D perovskite layer and the 2D perovskite passivation layer at room temperature, where the room temperature includes any temperature between 15 and 35° C.

### BRIEF DESCRIPTION OF THE DRAWINGS

For a more complete understanding of the present invention, reference is now made to the following descriptions taken in conjunction with the accompanying drawings, in which:

FIG. 1 is a schematic diagram of an inverted p-i-n PSC having a 3D/2D heterojunction annealed at room temperature;

FIG. 2 is a flow chart of a method for forming the inverted p-i-n PSC of FIG. 1;

FIG. 3 schematically illustrates the structure of a molecule used to form the 2D perovskite layers in the inverted p-i-n PSC structure;

FIG. 4A shows the structure of a 3D perovskite structure, FIG. 4B shows the formation of a 2DPP layer on top of the 3D perovskite structure using the molecule of FIG. 3 at thermal annealing at 80 to 120° C., and FIG. 4C shows the formation of plural 2DPP layers having different structures, on top of the 3D perovskite structure using the molecule of FIG. 3 at room temperature;

FIG. 5 shows the integrated intensity of grazing-incidence wide-angle X-ray scattering on the perovskite films with and without 2DPP layer;

FIG. 6 shows the cross-sectional transmission electron microscopy image of 2D/3D heterojunctions of the device of FIG. 1;

FIG. 7A shows the normalized PL spectra of each 2DPP layer from low to high wavelengths while FIG. 7B shows the energy level scheme for the control perovskite and with 2DPP films together with hole transport layer (2PACz) and electron transport layers (C₆₀);

FIG. 8 shows the false-gray colored cross-sectional SEM view of the device of FIG. 1;

FIG. 9 shows the current density J versus voltage V scan of the PSC devices with and without 2DPP layer of FIG. 1 when manufactured 2DPP layer under thermal annealed (TA) conditions and at room temperature (RT) conditions;

FIGS. 10A to 10D show the statistical distribution of the device parameters for the device shown in FIG. 1 with and without 2D perovskite layers; the data in these figures illustrate 60 pixels from several subsequent batches;

FIG. 11 illustrates the variation of the PCEs at damp-heat test of encapsulated devices formed with various 2DPP layers;

FIG. 12 illustrates continuous maximum power point (MPP) tracking for the encapsulated control solar cell and the 2DPP layer formed at RT cell under AM 1.5 standard spectrum illumination in ambient air and the inset is a photograph of the encapsulated perovskite solar cells of FIG. 1; and

FIG. 13 illustrates a solar cell panel having plural solar cells as shown in FIG. 1.

### DETAILED DESCRIPTION OF THE INVENTION

The following description of the embodiments refers to the accompanying drawings. The same reference numbers in different drawings identify the same or similar elements. The following detailed description does not limit the invention. Instead, the scope of the invention is defined by the appended claims. The following embodiments are discussed, for simplicity, with regard to a solar cell that includes a 3D/2D perovskite heterojunction for inverted p-i-n devices through tailoring of the dimensionality of the 2D material (i.e., control over the number, n, of its octahedral inorganic sheets) with a thermal annealing-free step. However, the embodiments to be discussed next are not limited to a solar cell but may be applied to any other device that uses perovskite layers.

Reference throughout the specification to “one embodiment” or “an embodiment” means that a particular feature, structure or characteristic described in connection with an embodiment is included in at least one embodiment of the subject matter disclosed. Thus, the appearance of the phrases “in one embodiment” or “in an embodiment” in various places throughout the specification is not necessarily referring to the same embodiment. Further, the particular features, structures or characteristics may be combined in any suitable manner in one or more embodiments.

According to an embodiment, a novel solar cell has a 3D/2D perovskite heterojunction formed for an inverted p-i-n device through tailoring of the dimensionality of the 2D material (i.e., control over the number, n, of its octahedral inorganic sheets) with thermal annealing at room temperature. In one application, the inventors have fabricated damp and heat stable PSCs by tailoring the dimensional fragments of 2DPP layers, formed at room temperature with oleylammonium-iodide (OLAI) molecules as the 2D perovskite cations. These molecules passivate the perovskite surface at the electron selective contact. The resulting inverted (p-i-n) PSCs deliver a PCE of 24.3% and retain >95% of their initial value after >1000 hours at damp-heat test conditions, thereby meeting one of the critical industry stability standards for photovoltaic modules. Details of this solar cell are now discussed with regard to the figures.

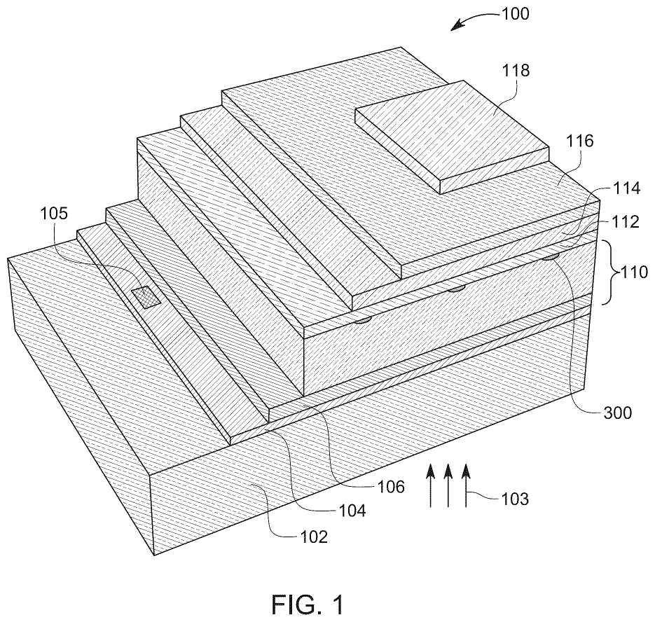

As discussed above, the degradation of encapsulated PSCs is usually caused by leakage in the packaging and device-related material instability. For experimental purposes, the inventors have developed a leakage-free device packaging that seals the perovskite within two glass sheets, using a vacuum-laminated encapsulant and edge-sealing via butyl rubber. Despite this sealing, damp-heat testing of the encapsulated control devices resulted in fast degradation, implying an intrinsic thermal instability of the perovskite absorber layer itself. In other words, just enclosing the semiconductor device with a seal which prevents ambient elements to enter the semiconductor device is not enough for long-term device stability. This specific issue is addressed by the present embodiment. More specifically, FIG. 1 shows a p-i-n PSC 100 in which the dimensionality (n) of the 2DP fragments is tailored at the electron-selective interface (C₆₀ layer 114 in the figure) to enable an efficient top-contact passivation via 2DPP layers 112. This interface is frequently ignored in the art because it is assumed that the conventional electron-selective layer 114, i.e., C₆₀ or its derivatives, provides sufficient passivation of the 3DPs 110. For this reason, the research community predominantly focused on the hole-selective interface 106 of the p-i-n PSCs, at the bottom of the device. However, recent reports have revealed that the C₆₀ is only weakly bonded to the perovskite layers and yields a high energetic disorder between perovskite and the C₆₀ layers, limiting their performance at elevated operating temperatures [7]. Moreover, a thin layer 114 of C₆₀ is insufficient to effectively protect the 3DP film 110 underneath from moisture or oxygen ingress. Thus, implementing 2DPP layers 112 stands as a promising approach to solving all the issues mentioned above.

The p-i-n PSC is formed on a substrate 102, which may be glass. Other materials may be used. An indium tin oxide (ITO) layer 104 is located over the substrate 102 and acts as the positive electrode. In this embodiment, both the substrate 102 and the ITO layer are transparent to solar light 103. A positive electrode 105 may be formed on the ITO layer 104. A hole layer extraction 106, for example, made of ([2-(9H-carbazol-9-yl)ethyl]phosphonic acid), 2PACz, is located over the ITO layer 104. The ITO layer 104 and/or the 2PACz layer 106 form the p-type part of the p-i-n junction. The perovskite 3D layer 110 is located over the 2PACz layer 106 and it forms the i-type part of the p-i-n junction. The 2DPP layers 112 are formed on top of the 3DP layer 110. In this embodiment, Cs_{0.03}(FA_{0.90}MA_{0.10})_{0.97}PbI₃ has been used as the perovskite material. Other combinations and ratios of the Cs, FA, MA, and PbI₃ materials may be used for the perovskite layer. In fact, any perovskite type material having the structure ABX₃ may be used, where A is an organic component or an inorganic component, B is an metal, and X is a halide. In one application, the A is selected from Cs⁺, Rb⁺, CH₃NH₃⁺, and HC(NH₂)₂⁺, B is selected from Pb²⁺, Sn²⁺, Ge²⁺, Mg²⁺, Ca²⁺, Sr²⁺, Ba²⁺, Cu²⁺, Fe²⁺, Pd²⁺, and Eu²⁺, and X is a halogen Cl⁻, Br⁻ or I⁻). The 2DPP layer 112 is formed over the upper surface of the 3DP layer 110, as discussed later. The 2DPP layer 112 has a thickness between 10 and 20 nm.

An electron selection layer 114 is located over the 2DPP layers 112, and this layer may be made of C₆₀, which is electron deficient and serves to extract electrons from the heterojunction. A bathocuproine (BCP) buffer layer 116 is located on the electron selection layer 114 to act as a buffer layer and improve the performance of the entire cell. Finally, a negative electrode 118, for example, made of Ag or Cu, is located on the BCP layer 116. While specific materials have been disclosed for the various layers discussed above, one skilled in the art, based on hindsight of the present disclosure, would understand that other materials or derivative of the used materials may be used to achieve the same results. For example, the specific perovskite material disclosed herein may be slightly changed to alter the ratio of Cs atoms to the FA_{0.90}MA_{0.10} composition, or an entirely different perovskite material may be used.

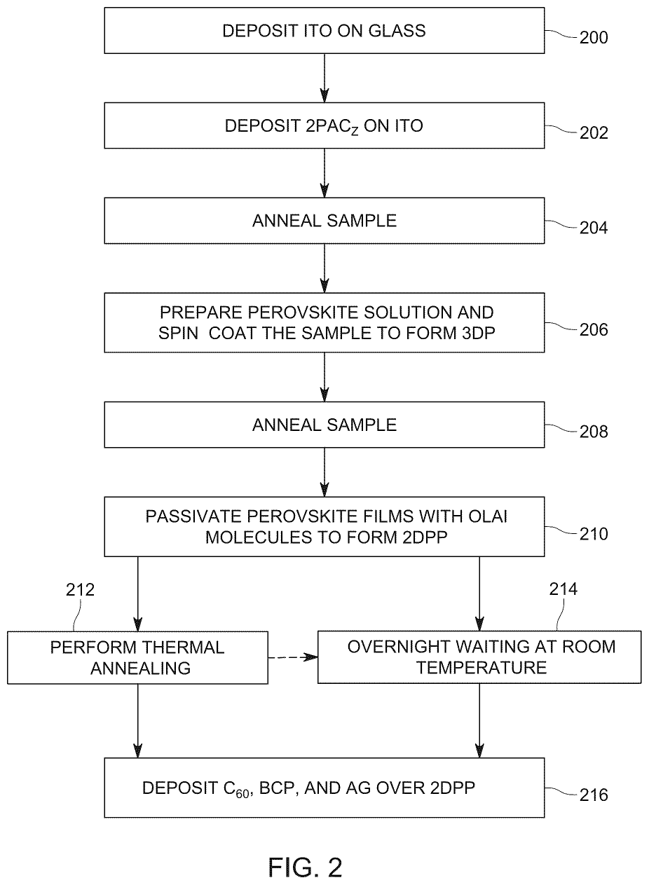

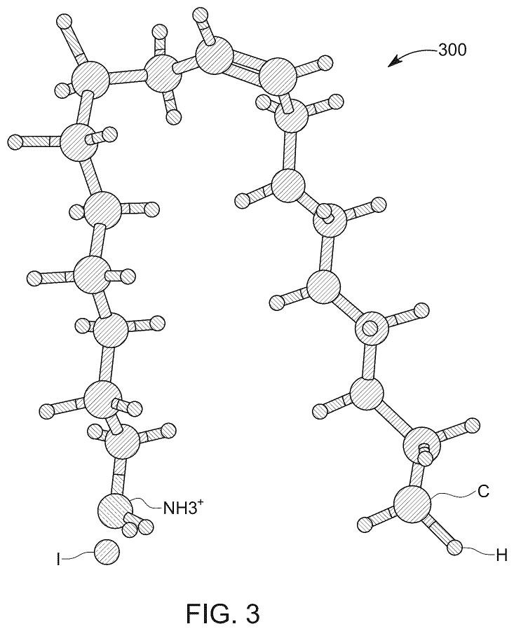

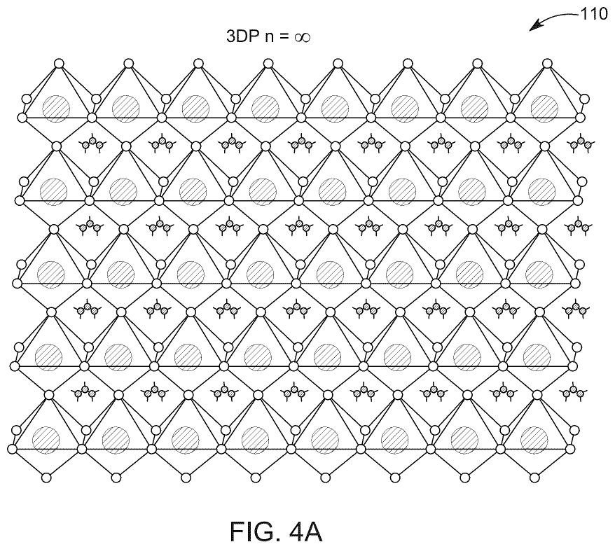

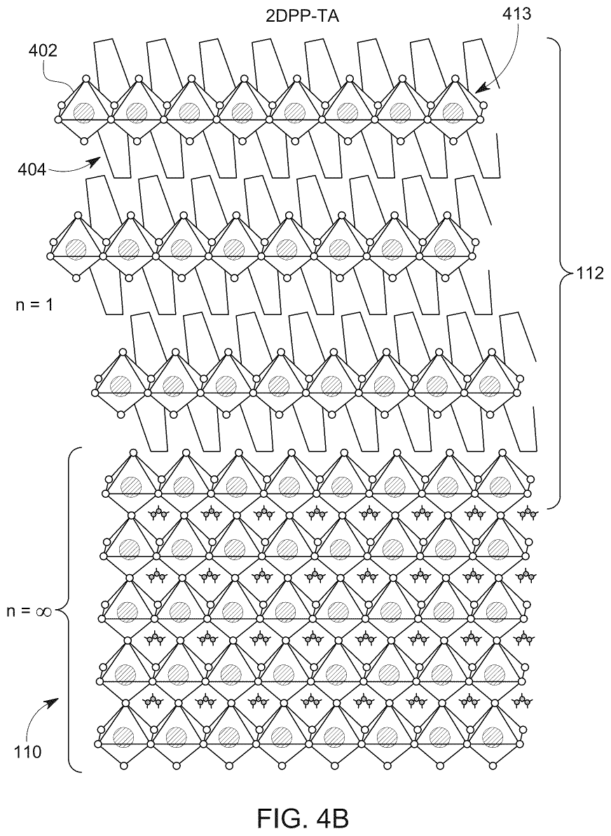

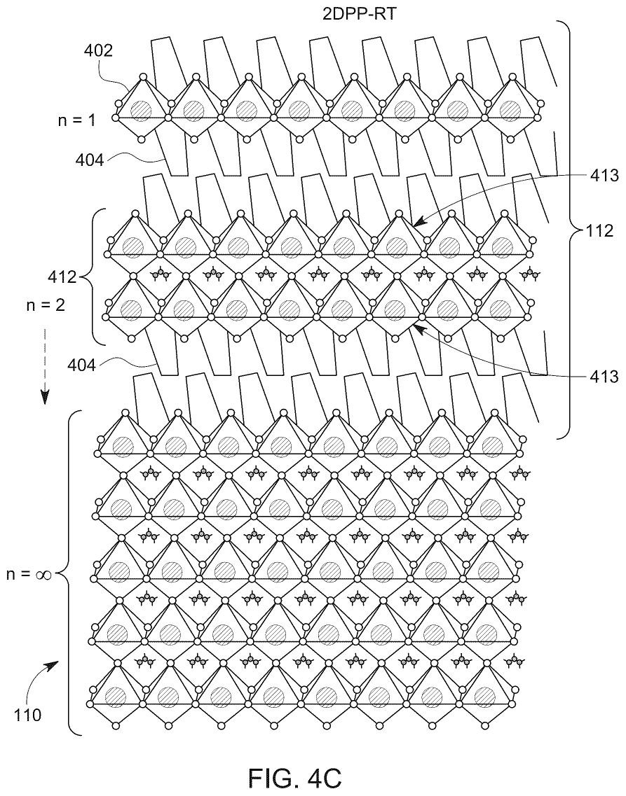

A method for making the solar cell 100 is now discussed with regard to FIG. 2. In step 200, the ITO layer 104 was deposited on the glass substrate 102. The ITO/glass was sequentially cleaned with acetone and IPA for 15 min, respectively. Before use, the ITO/glass substrates were cleaned with ultraviolet ozone for 15 min. Then, in step 202, the ITO/glass substrates were spin-coated with a thin layer 106 of a self-assembled monolayer (SAM) 2PACz at 5,000 r.p.m. for 30 s followed by a step 204 of annealing at 100° C. for 10 min (0.5-1.0 mg/mL in Ethanol). A mixture of perovskite solution (1.5 M) composed of mixed cations (Pb, Cs, FA, and MA) was dissolved in a mixed solvent (dimethylformamide (DMF)/dimethylsulfoxide (DMSO) with 4/1 ratio) in step 206, according to a formula of Cs_{0.03}(FA_{0.90}MA_{0.10})_{0.97}PbI₃. A two-step spin-coating procedure with 2,000 r.p.m. for 40 s and 6,000 r.p.m. for 10 s was adopted to prepare the 3D perovskite film 110. Anisole (300 μl) was dropped on the spinning substrate during the last 10 s of the second spin-coating step. Subsequently, the sample was annealed in step 208 at 100° C. for 30 to 60 min. After cooling down, the 2DP passivation by solution post-treatment was carried in step 210. Olaylammonium iodide (OLAI) molecules 300 (see FIGS. 1 and 3) were dissolved in chloroform with concentrations ranging from 0.5 to 2.5 mg/mL. Then, this 2D ligand solution (100 μmL) including the OLAI molecules 300 was spin-coated onto the as-prepared 3D perovskite film 110 at 5,000 r.p.m. for 25 s, to form the 2DPP layer 112. The inventors found that the —NH₃ group of the OLAI molecule interacts with the Pb and I atoms of the perovskite material of the layer 110 and that the binding energy is about −1.55 eV. Then the treated perovskite films 110 developed the 2DPP layer 112 and this layer 112 was annealed in step 212 at 100° C. for 10 min to obtain 2DPP-TA-based samples, i.e., 2D perovskite layers that have n=1. An additional or alternate step 214 may be performed at room temperature to obtain the 2DPP-RT-based samples, and thus these samples were the stored overnight at room temperature. The room temperature is defined in this application as being any temperature between 35 and 15° C. In one embodiment, the room temperature is defined to be 25° C.+/−10%. This step (room temperature annealing instead of TA annealing) is used to obtain values of n equal to or larger than 2 and also to obtain plural sub-layers of the 2D perovskite material forming the layer 112 of 2D perovskite material. By controlling the concentration of the OLAI molecules and/or the temperature of the solutions used when forming the 2D layer 112, the resulting 2DPP layer 112 may include plural sub-layers 402, 412, as discussed next with regard to FIGS. 4A to 4C. After 2DP passivation, the treated films were then washed one time with chloroform at 5,000 r.p.m. for 20 s to remove unbounded 2D ligands. All steps were performed in an N₂ glove box. After the perovskite deposition, the samples were transferred into a thermal evaporator for the C₆₀ (25 nm) and BCP (5 nm) deposition in step 216. For the final step 216, a 120 nm thick Ag or Cu layer was evaporated at low pressure (<10⁻⁶ Torr) with an area of ˜0.1 cm².

A short discussion about the differences between 2D and 3D perovskite films is now presented. The 3D halide perovskite is characterized by the molecular formula ABX₃, where A=organic or inorganic monovalent cation (e.g., MA⁺ (methylammonium), FA⁺ (formamidinium) or Cs⁺) at the apex angle of the face-centered cubic lattice, B=divalent cation (e.g., Pb²⁺ or Sn²⁺), located in the body of the cubic crystal, and X=halogen (e.g., Cl⁻, Br⁻ or I⁻) in the face-centered. The 2D perovskite is formed by introducing an bulky organic functional group into a 3D perovskite, using a Ruddlesden-Popper crystal structure with the formula (RNH₃)₂Aₙ₋₁MₙX₃ₙ₊₁, (n=1, 2, 3, 4 . . . ), wherein (Aₙ₋₁MₙX₃ₙ₊₁)²⁻ represents a conductor layer derived from the parent 3D perovskite, such as cesium (Cs) lead iodide (CsPbI₃). The conductor layer is isolated by R—NH₃ (e.g., a large aliphatic or aromatic alkyl ammonium spacer cation such as butylammonium (BA) and phenethylammonium (PEA)). n=∞ constitutes a 3D structure; n=1 corresponds to a pure 2D structure and when the value of n is larger than 1, for example 2, it is a quasi-2D structure. Thus, the chemical structure of the 2D perovskite is different from the chemical structure of the 3D perovskite as the 2D perovskite includes the additional R—NH₃ organic material. In this embodiment, the R—NH₃ is the OLAI molecule 300.

The relevance of steps 212 and 214 is now discussed. The post-treatment of the surface defects of the 3DP layer 110 via the application of the OLAI molecules 300 (see FIGS. 1 and 3) to form Ruddlesden-Popper phase 2DP layers 112, results in higher PCEs and prolonged stabilities of the p-i-n PSCs 100. Note that a Ruddlesden-Popper (RP) phase is a type of perovskite structure that consists of two-dimensional perovskite-like planes or slabs interleaved with cations. The dimensionality n introduced above describes how many slabs or planes are interleaved with cations. More specifically, FIGS. 4A to 4C show various configurations of the 2DPP layers 112. FIG. 4A schematically illustrates the configuration of the 3DP layer 110, which is considered to be the control sample. Because no slab or plane of perovskite material is interleaved with the cations, the dimensionality of n is considered to be infinity. FIG. 4B shows the formation of the 2DPP layers 112 with n=1, i.e., only one sub-layer 402 of perovskite is interleaved with cations 404 (for example, the OLAI molecules). In other words, the sub-layer 402 of low dimensional perovskite is anchored to the 3DP layer 110 with the cations 404. The 2DPP layer 112 may include plural sub-layers 402 (having a single plane 413, where the term “plane” herein is understood to mean a single sheet of octahedral inorganic material) separated by cations, and this structure was obtained during step 212, i.e., by thermal annealing (TA). However, if the post-treatment of the layers 112 is performed at room temperature (RT), i.e., by step 214, instead of thermal annealing, then the structure of these sub-layers 402, 412 is as shown in FIG. 4C, where two planes 413 of the perovskite material form the sub-layer 412, and the sub-layers 402 and 412 are interleaved with the cations 404, i.e., the dimensionality n=2. The cations 404 anchor the plural sub-layers 402, 412 to each other and to the 3D layer 110. Note that for n=2 sub-layers 412 in FIG. 4C, there are also n=1 sub-layers 402 formed in the 2D perovskite layer 112. The inventors have discovered that by controlling the post-treatment temperature of the 2D ligand solution and the concentration of the OLAI molecule 300 during the formation of the 2DPP layers 112, it is possible to obtain sub-layers with n=1, and/or n=2, and/or other larger values. In one application, the 2D perovskite layer 112 include plural dimensionalities, e.g., n is 1 for some sub-layers 402, 2 for other sub-layers 412, and so on, up to n=10. The number of sub-layers 402, 412, etc. in the 2D perovskite layer 112 may be between 2 and 15 when the layer 112 is formed under RT conditions. Note that this is not possible under TA conditions and when no OLAI molecules are used to obtain sub-layers with n larger than one. The 2D perovskite layers obtained by TA are called herein “2DPP-TA” while the 2D perovskite layers obtained by RT are called “2DPP-RT.” Tailoring the dimensionality n of the 2DP sublayers 402, 412—which also dictates their optical and electronic properties—is achieved by tuning the annealing conditions, i.e., exploiting the fact that higher-n layers feature a lower formation energy. In this regard, the 2DPP layers 112 with n=1 are usually formed by thermal annealing (2DPP-TA). Contrastingly, the inventors found that the formation of higher-dimensionality 2DP layers (n≥2) becomes more pronounced when the post-treatment is performed at room temperature (2DPP-RT) when using the OLAI molecule as shown in the schematic illustration in FIGS. 4A to 4C.

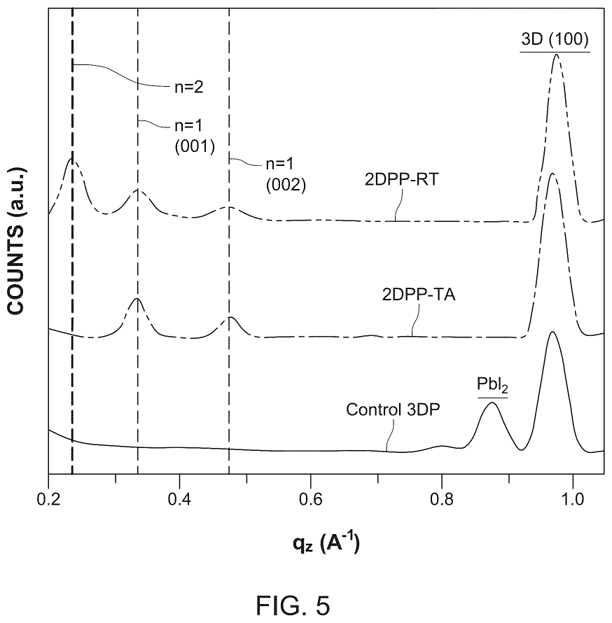

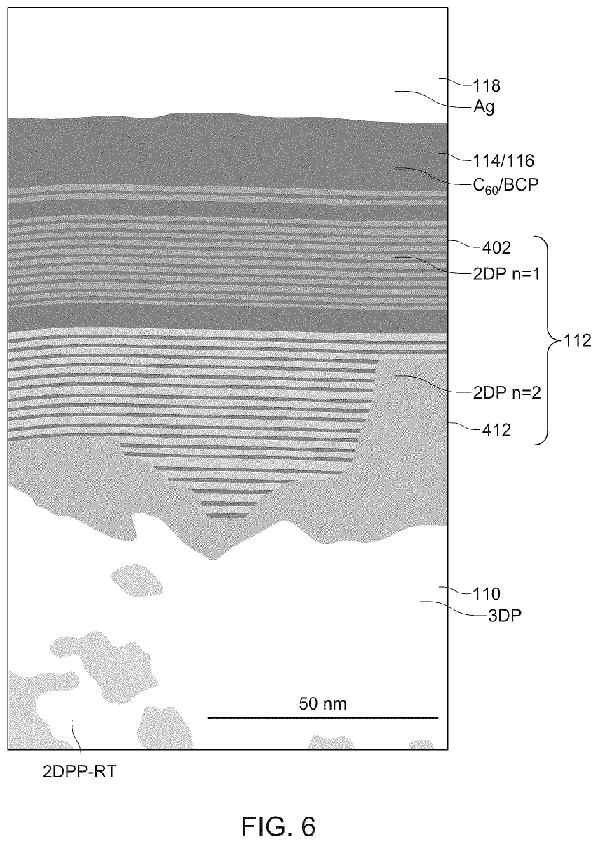

The formation of the 2DPP layers 112 on the 3DP absorber layer 110 was investigated via grazing-incidence wide-angle X-ray scattering, as illustrated in FIG. 5. It was found that the 2DPP films 112 exhibit diffraction q_{z} peaks at ˜0.2 A⁻¹ to ˜0.5 A⁻¹, corresponding to the (001) and (002) planes of 2DP crystals. As expected, the 2DPP-TA films 402 are dominated by n=1 layers (with a prominent peak at q_{z}˜0.35 A−1), while higher dimensionality 2DP films 412 (n=2) are associated with a peak at lower q_{z}. The strong intensity in the z-direction for 2DPP films indicates the highly oriented lateral direction of the top 2DP layers. Cross-sectional high-resolution scanning transmission electron microscopy (HR-STEM) images shown in FIG. 6 confirm the gradation of the 2DP dimensionality from n=2 to 1, from bottom to upper layers of 2DPP-RT samples. Elemental mapping images (not shown) also confirm this by showing a reduction of the density of C, Pb, and I elements.

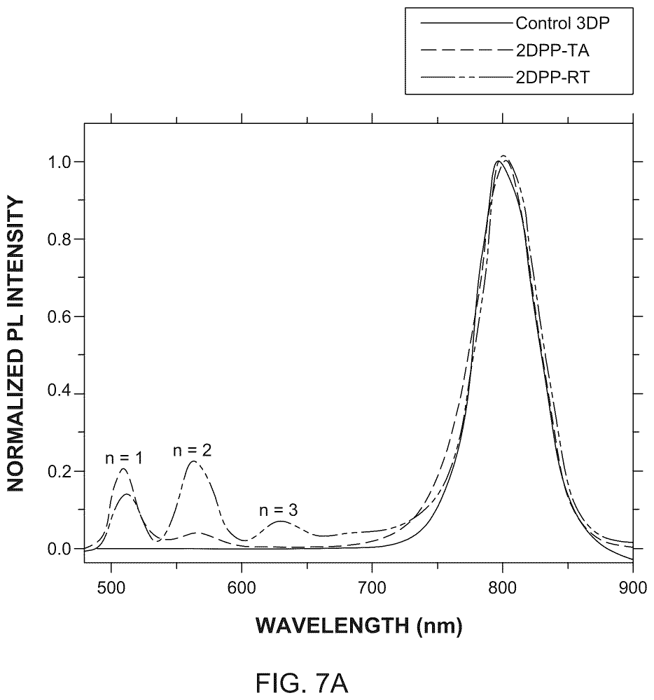

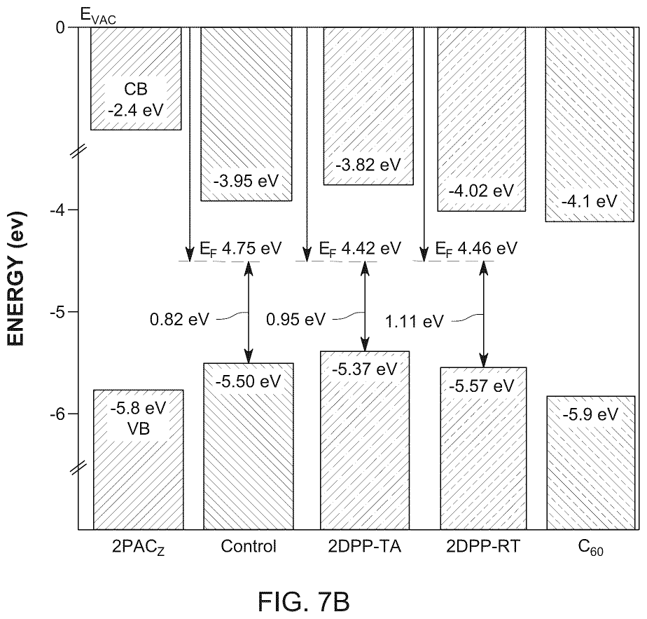

Scanning electron microscopy (SEM) top-view images (not shown) revealed that the surface morphology of the perovskite films after 2DPP does not change significantly. Further, the 2DPP films exhibited higher photoluminescence (PL) emission and longer PL decay lifetime than control 3DP films because of the suppression of non-radiative recombination caused by trap states at the surface. Notably, the 2DP (n=2) capping layer 112 is formed uniformly on top of 3DP surfaces 110 for 2DPP-RT, as shown in the PL images in FIG. 7A. Both the 2DPP-TA and 2DPP-RT films resulted in the formation of n=1 layers, which is observed from the emission at ˜510 nm, in accordance with the literature. Interestingly, the 2DPP-RT films 112 exhibit additional PL peaks at longer wavelengths that indicate higher dimensional fragments (n=2 and n=3) of 2DP with discontinuous crystal formation.

The energy-level diagrams of 2PACz (anchored on ITO, and used here as hole-selective contact), perovskites, and C₆₀ are shown in FIG. 7B. With the OLAI post-treatment, the E_{cutoff} shifts to a higher binding energy, indicating that the ion-exchange-induced 3DP to 2DP phase transition can lower the Fermi level (EF) of post-treated perovskite films. Notably, the energetic gap between EF and valence band maximum (VBM) of the 2DPP-RT sample is wider, indicating the enhanced n-type character of post-treated 3DP films, likely attributable to a successful 2DPP strategy. Besides, the CBM of the 2DPP-RT films is also closer to the conduction band minimum (CBM) of C₆₀ layer at the n-type contact, resulting in more efficient charge transfer at the 3DP/2DP and C₆₀ electron-selective layer. Contrastingly, the CBM of 2DPP-TA films is much higher than the CBM of C₆₀ with less n-type character, resulting in less efficient charge transfer of 3DP/2DP at the n-contact. The effects of the 2DP formation on the 3DP surfaces have been confirmed by several characterization techniques such as atomic force microscopy, contact angles, and X-ray photoelectron spectroscopy.

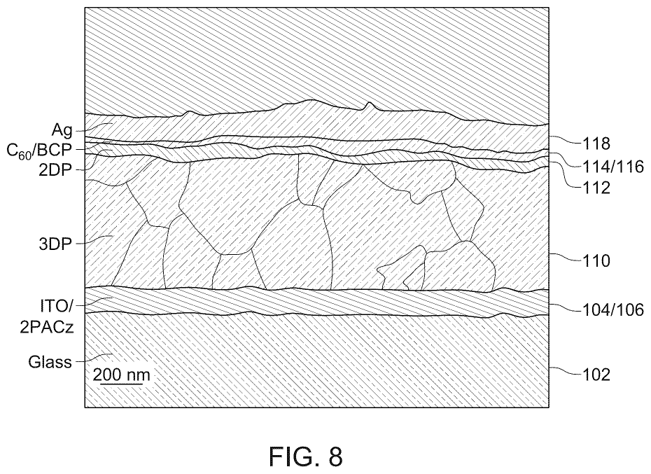

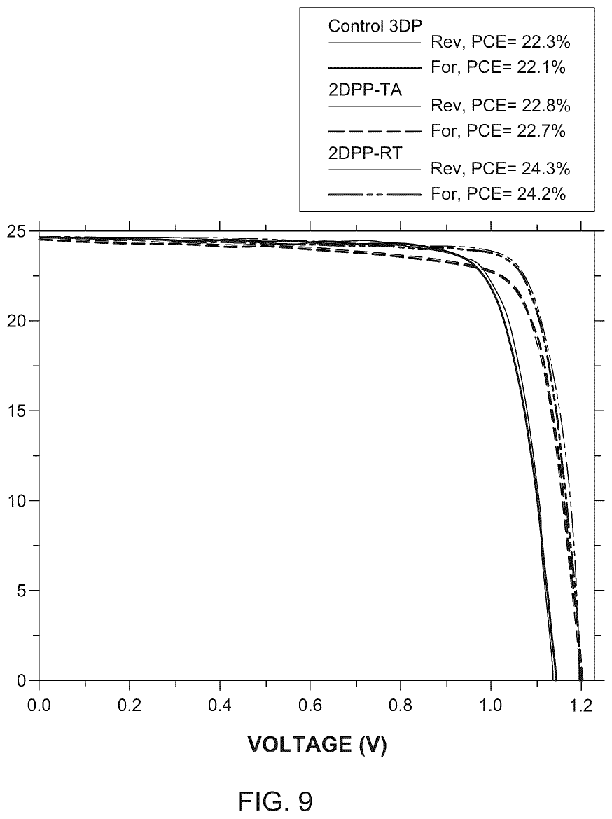

FIG. 8 shows the false-gray colored cross-sectional SEM view of these devices. As shown in the current density-voltage (J-V) characteristics of various devices (pure 3DP, 2DPP-TA, and 2DPP-RT), as illustrated in FIG. 9, the 2DPP-RT devices demonstrate substantially improved PCEs with a maximum PCE of 24.3% and stabilized PCE of ˜24% (VOC of ˜1.20 V and FF of ˜82%). These results represent an absolute ˜2% PCE gain upon the 2DPP-RT device, giving the one of the highest PCE for inverted PSCs.

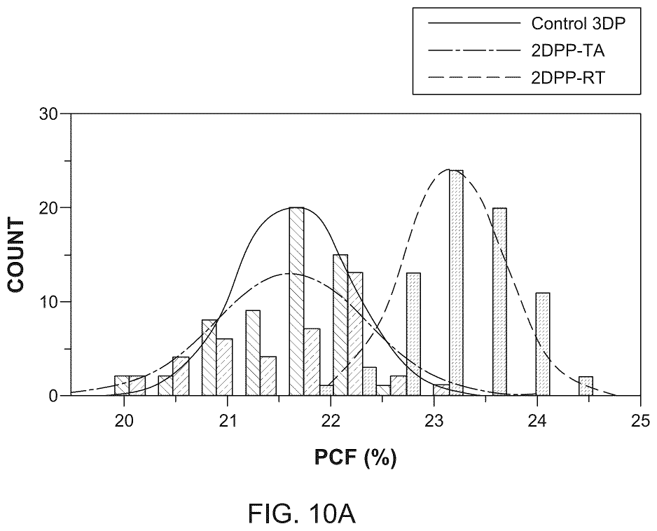

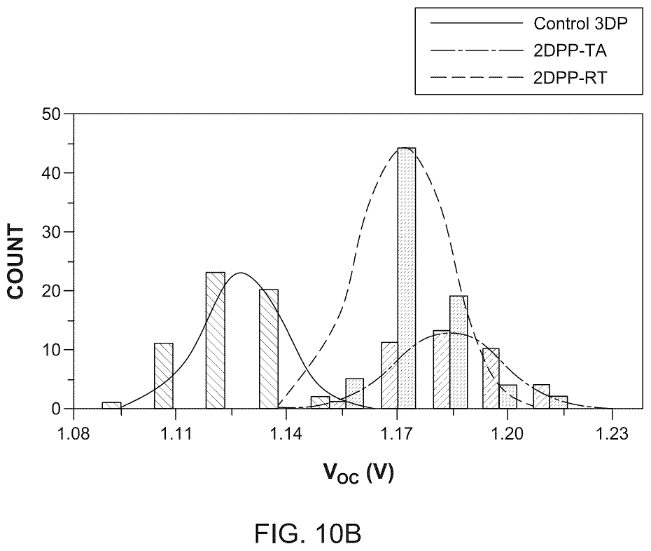

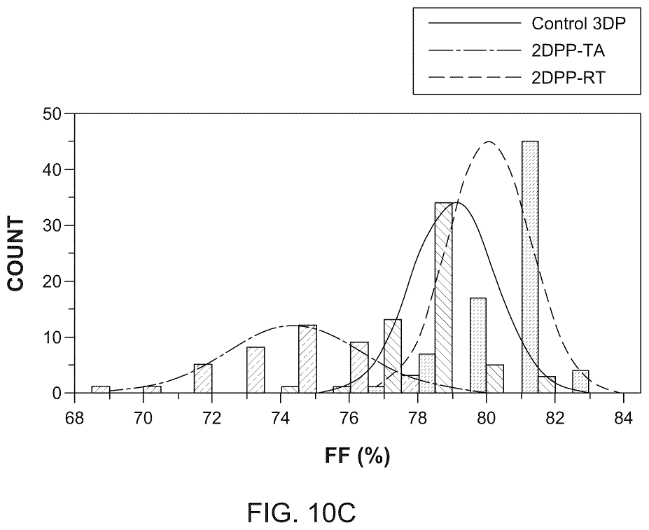

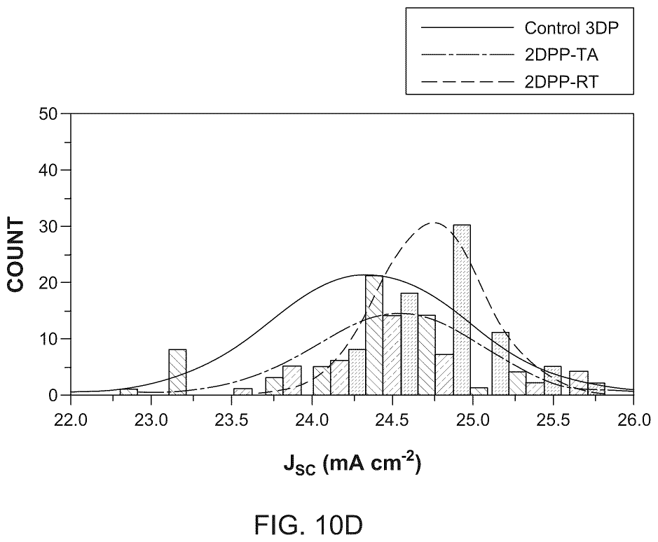

Also, the 2DPP-RT layers 112 enable to minimize the energy loss (Eₗₒₛₛ=E_{g}−q_{VOC}) up to 0.34 eV, which represents about 96% of the thermodynamic limit of the VOC (1.27 V) for the optical bandgap (E_{g}) of 1.55 eV. This loss is even lower than for state-of-the-art monocrystalline silicon solar cells (0.36 V). In contrast, the 2DPP-TA devices suffer from lower FF (<79%) values, indicative of the energy level mismatch at the electron contact, as derived from the ultraviolet photoelectron spectroscopy (UPS) results. The statistical distribution of the PCE, VOC, FF, and JSC values of these studied devices are shown in FIGS. 10A to 10D, confirming the high reproducibility of the approach illustrated in FIG. 1.

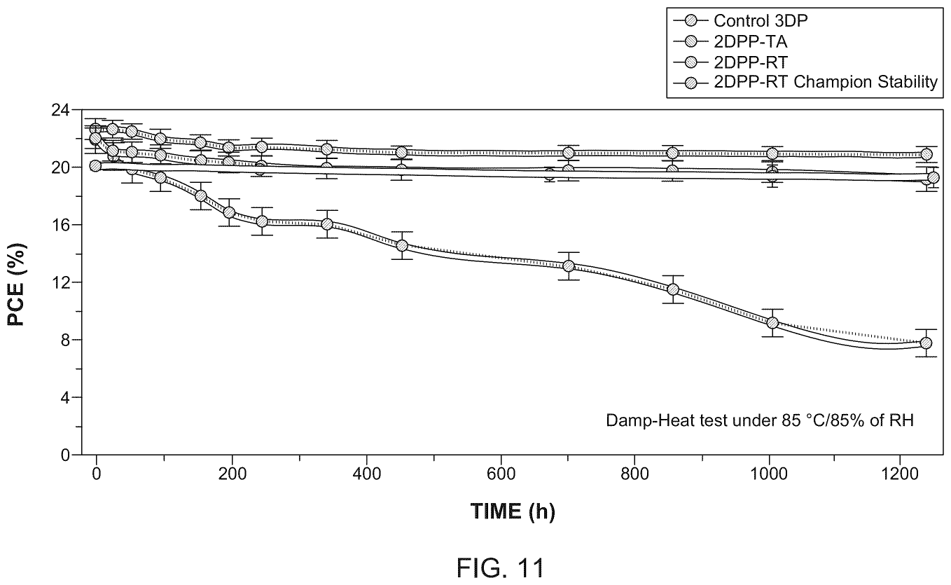

The 2DPP-treated PSCs 100 were subjected to a set of rigorous stability tests. First, the stability of the encapsulated devices was tested when subjected to industry-relevant damp-heat tests. For this test, the 2DPP layers 112 simultaneously serve as ion-migration-blocking, moisture/oxygen ingress barriers, and defect passivation layers, particularly at elevated operating temperatures. In this regard, the 2DPP-RT-based devices retained >95% of the initial PCE (T95) after >1200 h for champion stability cells, as shown in FIG. 11. Remarkably, after the damp-heat test, three devices showed an average PCE of 19.3%. These results represent the successful encapsulated PSCs passing industry-relevant damp-heat test according to the IEC 61215:2016 standards. Also, the final PCE>19% after >1000 h of damp-heat test, represents the highest retained PCE among all previously reported PSCs. It is noted that there is no significant change in the structural and optical properties of the 2DPP films (both 3DP and 2DP) after >1000 h thermal annealed at 85° C., confirming the robustness of the 2DPP approach.

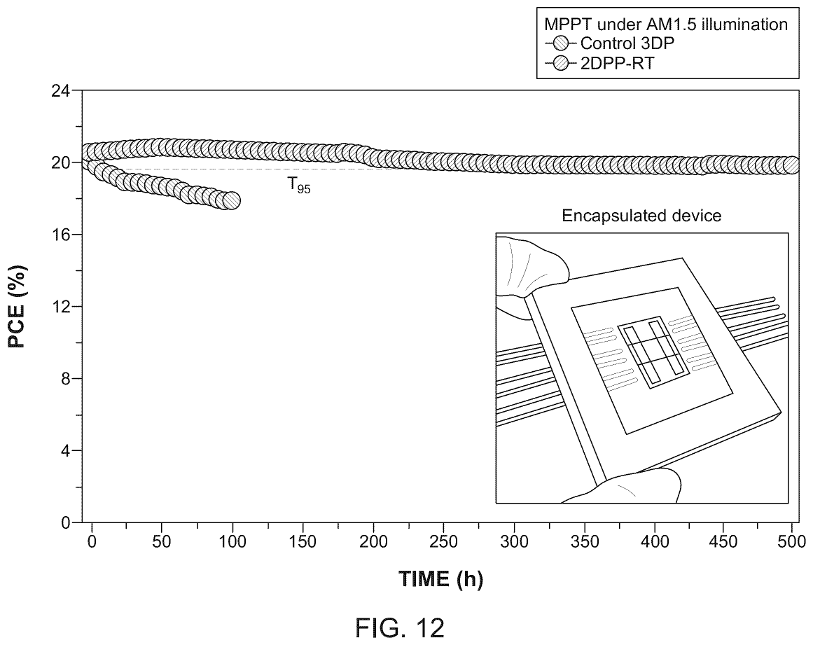

Next, the inventors also tested the encapsulated PSCs with the maximum power point tracking (MPPT) under 1-sun illumination in ambient air for >500 h, as shown in FIG. 12. The effective 2DPP has shown critical roles for stability and PCE improvements in PSCs. Here, the 2DPP-RT-based devices 100 retained up to ˜95% of their initial PCE after an MPPT test of >500 h, while the control devices retained their PCE<90% for only around 100 h.

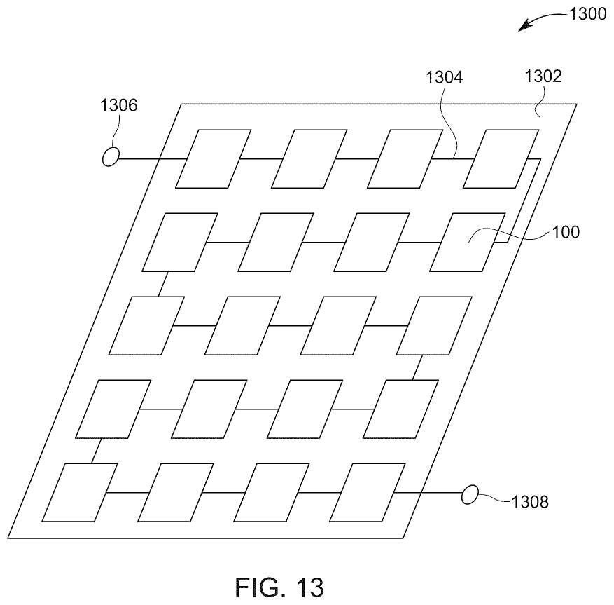

The inverted p-i-n structure 110/112 can be implemented to metal-halide perovskite-based products for optoelectronic industries such as solar cells, light emitting diodes (LEDs), transistors, photodetectors, laser, optical amplifiers, X-ray detectors, scintillators which can be either in thin film form, nanocrystals, or single-crystals by passivating their surface defects and improve their optoelectronic quality. For example, FIG. 13 shows a solar cell panel 1300 having plural PSC cells 100 on a substrate 1302. The cells 100 are electrically connected to each other through wiring 1304 and at least two terminals 1306 and 1308 exit the panel for providing the generated electric power. There is no limitation for the metal halide perovskite composition as long as it contains metal and halides together. Specifically, in the solar cells field, the application is not limited by only single-junction perovskite solar cells, it can be applied also to perovskite/silicon tandem solar cells, and all-perovskite tandem solar cells.

The disclosed embodiments provide an inverted p-i-n PSC with 2DP passivation layers that prevent PCE degradation under damp-heat conditions. It should be understood that this description is not intended to limit the invention. On the contrary, the embodiments are intended to cover alternatives, modifications and equivalents, which are included in the spirit and scope of the invention as defined by the appended claims. Further, in the detailed description of the embodiments, numerous specific details are set forth in order to provide a comprehensive understanding of the claimed invention. However, one skilled in the art would understand that various embodiments may be practiced without such specific details.

Although the features and elements of the present embodiments are described in the embodiments in particular combinations, each feature or element can be used alone without the other features and elements of the embodiments or in various combinations with or without other features and elements disclosed herein.

This written description uses examples of the subject matter disclosed to enable any person skilled in the art to practice the same, including making and using any devices or systems and performing any incorporated methods. The patentable scope of the subject matter is defined by the claims, and may include other examples that occur to those skilled in the art. Such other examples are intended to be within the scope of the claims.

### REFERENCES

The entire content of all the publications listed herein is incorporated by reference in this patent application.
[1] Y.-H. Lin, N. Sakai, P. Da, J. Wu, H. C. Sansom, A. J. Ramadan, S. Mahesh, J. Liu, Robert D. J. Oliver, J. Lim, L. Aspitarte, K. Sharma, P. K. Madhu, A. B. M.-Vilches, P. K. Nayak, S. Bai, F. Gao, C. R. M. Grovenor, M. B. Johnston, J. G. Labram, J. R. Durrant, J. M. Ball, B. Wenger, B. Stannowski, H. J. Snaith, A piperidinium salt stabilizes efficient metal-halide perovskite solar cells. Science 369, (2020). DOI: 10.1126/science.aba1628.
[2] J. Jeong, M. Kim, J. Seo, H. Lu, P. Ahlawat, A. Mishra, Y. Yang, M. A. Hope, F. T. Eickemeyer, M. Kim, Y. J. Yoon, I. W. Choi, B. P. Darwich, S. J. Choi, Y. Jo, J. H. Lee, B. Walker, S. M. Zakeeruddin, L. Emsley, U. Rothlisberger, A. Hagfeldt, D. S. Kim, M. Grätzel, J. Y. Kim, Pseudo-halide anion engineering for α-FAPbI3 perovskite solar cells. Nature 592, 381-385 (2021). DOI:10.1038/s41586-021-03406-5
[3] S. Chen, X. Dai, S. Xu, H. Jiao, L. Zhao, J. Huang, Stabilizing perovskite-substrate interfaces for high-performance perovskite modules. Science 373, 902-907 (2021). DOI:10.1126/science.abi6323.
[4] R. Wang, J. Xue, K.-L. Wang, Z.-K. Wang, Y. Luo, D. Fenning, G. Xu, S. Nuryyeva, T. Huang, Y. Zhao, J. L. Yang, J. Zhu, M. Wang, S. Tan, I. Yavuz, K. N. Houk, Y. Yang, Constructive molecular configurations for surface-defect passivation of perovskite photovoltaics. Science 366, 1509-1513 (2019). DOI:10.1126/science.aay9698.
[5] H. Zhou, Q. Chen, G. Li, S. Luo, T.-b. Song, H.-S. Duan, Z. Hong, J. You, Y. Liu, Y. Yang, Interface engineering of highly efficient perovskite solar cells. Science 345, 542-546 (2014). DOI:10.1126/science.1254050.
[6] Y.-W. Jang, S. Lee, K. M. Yeom, K. Jeong, K. Choi, M. Choi, J. H. Noh, Intact 2D/3D halide junction perovskite solar cells via solid-phase in-plane growth. Nat. Energy 6, 63-71 (2021). DOI:10.1038/s41560-020-00749-7.
[7] Y. Lin, Y. Bai, Y. Fang, Z. Chen, S. Yang, X. Zheng, S. Tang, Y. Liu, J. Zhao, J. Huang, Enhanced thermal stability in perovskite solar cells by assembling 2D/3D stacking structures. J. Phy. Chem. Lett. 9, 654-658 (2018). DOI:10.1021/acs.jpclett.7b02679.
[8] J. J. Yoo, S. Wieghold, M. C. Sponseller, M. R. Chua, S. N. Bertram, N. T. P. Hartono, J. S. Tresback, E. C. Hansen, J.-P. Corea-Baena, V. Bulović, T. Buonassisi, S. S. Shin, M. G. Bawendi, An interface stabilized perovskite solar cell with high stabilized efficiency and low voltage loss. Energy Environ. Sci. 12, 2192-2199 (2019). DOI: 10.1039/c9ee00751 b.
[9] E. H. Jung, N. J. Jeon, E. Y. Park, C. S. Moon, T. J. Shin, T.-Y. Yang, J. H. Noh, J. Seo, Efficient, stable and scalable perovskite solar cells using poly(3-hexylthiophene). Nature 567, 511-515 (2019). DOI:10.1038/s41586-019-1036-3.
[10] A. H. Proppe, A. Johnston, S. Teale, A. Mahata, R. Quintero-Bermudez, E. H. Jung, L. Grater, T. Cui, T. Filleter, C.-Y. Kim, S. O. Kelley, F. De Angelis, E. H. Sargent, Multication perovskite 2D/3D interfaces form via progressive dimensional reduction. Nat. Commun. 12, 3472 (2021). DOI:10.1038/s41467-021-23616-9.
[11] G. Yang, Z. Ren, K. Liu, M. Qin, W. Deng, H. Zhang, H. Wang, J. Liang, F. Ye, Q. Liang, H. Yin, Y. Chen, Y. Zhuang, S. Li, B. Gao, J. Wang, T. Shi, X. Wang, X. Lu, H. Wu, J. Hou, D. Lei, S. K. So, Y. Yang, G. Fang, G. Li, Stable and low-photovoltage-loss perovskite solar cells by multifunctional passivation. Nat. Photon. 15, 681-689 (2021). DOI:10.1038/s41566-021-00829-4.
[12] Q. Yao, Q. Xue, Z. Li, K. Zhang, T. Zhang, N. Li, S. Yang, C. J. Brabec, H.-L. Yip, Y. Cao, Graded 2D/3D perovskite heterostructure for efficient and operationally stable MA-free perovskite solar cells. Adv. Mater. 32, 2000571 (2020). DOI:10.1002/adma.202000571.
[13] D. H. Cao, C. C. Stoumpos, O. K. Farha, J. T. Hupp, M. G. Kanatzidis, 2D homologous perovskites as light-absorbing materials for solar cell applications. J. Am. Chem. Soc. 137, 7843-7850 (2015). DOI:10.1021/jacs.5b03796.
[14] J. Yang, S. Xiong, J. Song, H. Wu, Y. Zeng, L. Lu, K. Shen, T. Hao, Z. Ma, F. Liu, C. Duan, M. Fahlman, Q. Bao, Energetics and energy loss in 2D ruddlesden-popper perovskite solar cells. Adv. Energy Mater. 10, 2000687 (2020). DOI: 10.1002/aenm.202000687.

1. A perovskite solar cell for converting solar energy into electricity, the perovskite solar cell comprising:
a substrate;
a 3D perovskite layer located on the substrate; and
a 2D perovskite layer directly located on the 3D perovskite layer,
wherein the 2D perovskite layer is anchored to the 3D perovskite layer with oleylammonium-iodide (OLAI) molecules, and
wherein each of the 2D and 3D perovskite layer includes the same perovskite material.

2. The perovskite solar cell of claim 1, wherein a dimensionality of the 2D perovskite layer is 2 or more.

3. The perovskite solar cell of claim 1, wherein the 2D perovskite layer includes at least two perovskite planes forming a single first sub-layer, and the two perovskite planes directly facing each other.

4. The perovskite solar cell of claim 3, wherein the 2D perovskite layer includes a second perovskite sub-layer that is separated from the single first sub-layer by a layer of OLAI molecules.

5. The perovskite solar cell of claim 4, wherein the 3D perovskite layer includes plural perovskite planes free of the OLAI molecules, and the plural perovskite planes are separated from the 2D perovskite layer by the OLAI molecules.

6. The perovskite solar cell of claim 1, further comprising:
a p-type layer which includes,
an indium tin oxide, ITO, layer formed directly on the substrate; and
a hole layer extraction layer formed directly on the ITO layer,
wherein the hole layer extraction includes ([2-(9H-carbazol-9-yl)ethyl]phosphonic acid), 2PACz.

7. The perovskite solar cell of claim 6, wherein the 3D perovskite layer is formed directly on the 2PACz layer.

8. The perovskite solar cell of claim 6, further comprising:
an n-type layer, which includes,
an electron selective layer formed directly on the 2D perovskite layer; and
a buffer layer formed directly on the electron selective layer,
wherein the electron selective layer includes C₆₀ and the buffer layer includes bathocuproine.

9. The perovskite solar cell of claim 8, further comprising:
a negative electrode formed on the n-type layer.

10. The perovskite solar cell of claim 1, wherein the perovskite material is Cs_{0.03}(FA_{0.90}MA_{0.10})_{0.97}PbI₃.

11. A solar cell module that converts solar energy into electrical energy, the solar cell module comprising:
a substrate;
plural solar cells formed onto the substrate; and
electrical connections that electrically connect in series the plural solar cells,
wherein a solar cell of the plural solar cells includes,
a 3D perovskite layer, and
a 2D perovskite layer directly located on the 3D perovskite layer,
wherein the 2D perovskite layer is anchored to the 3D perovskite layer with oleylammonium-iodide (OLAI) molecules, and
wherein each of the 2D and 3D perovskite layer includes the same perovskite material.

12. The solar cell module of claim 11, wherein a dimensionality of the 2D perovskite layer is 2 or more.

13. The solar cell module of claim 11, wherein the 2D perovskite layer includes at least two perovskite planes forming a single first sub-layer, and the two perovskite planes directly facing each other.

14. The solar cell module of claim 13, wherein the 2D perovskite layer includes a second perovskite sub-layer that is separated from the single first sub-layer by a layer of OLAI molecules.

15. The solar cell module of claim 14, wherein the 3D perovskite layer includes plural perovskite planes free of the OLAI molecules, and the plural perovskite planes are separated from the 2D perovskite layer by the OLAI molecules.

16. The solar cell module of claim 11, wherein the solar cell further comprises:
a p-type layer which includes,
an indium tin oxide, ITO, layer formed directly on a substrate; and
a hole layer extraction layer formed directly on the ITO layer,
wherein the hole layer extraction includes ([2-(9H-carbazol-9-yl)ethyl]phosphonic acid), 2PACz.

17. The solar cell module of claim 16, wherein the 3D perovskite layer is formed directly on the 2PACz layer.

18. The solar cell module of claim 16, wherein the solar cell further comprises:
an n-type layer, which includes,
an electron selective layer formed directly on the 2D perovskite layer; and
a buffer layer formed directly on the electron selective layer,
wherein the electron selective layer includes C₆₀ and the buffer layer includes bathocuproine.

19. The solar cell module of claim 11, wherein the perovskite material is Cs_{0.03}(FA_{0.90}MA_{0.10})_{0.97}PbI₃.

20. A method for forming a perovskite solar cell, the method comprising:
forming an indium tin oxide, ITO, layer on a substrate;
depositing a hole extraction layer on the ITO layer;
forming 3D perovskite layer on the hole extraction layer;
passivating a top surface of the 3D perovskite layer with oleylammonium-iodide, OLAI molecules to form a 2D perovskite passivation layer; and
annealing the 3D perovskite layer and the 2D perovskite passivation layer at room temperature,
wherein the room temperature includes any temperature between 15 and 35° C.
